(19) United States
(12) Patent Application Publication
(10) Pub. No.: US 2012/0217627 A1
(43) Pub. Date: Aug. 30, 2012

(54) PACKAGE STRUCTURE AND METHOD OF FABRICATING THE SAME

(75) Inventors: Tzyy-Jang Tseng, Taoyuan (TW); Dyi-Chung Hu, Taoyuan (TW); Yu-Shan Hu, Taoyuan (TW)

(73) Assignee: UNIMICRON TECHNOLOGY CORPORATION, Taoyuan (TW)

(21) Appl. No.: 13/191,793

(22) Filed: Jul. 27, 2011

(30) Foreign Application Priority Data
Feb. 24, 2011 (TW) 100106141

(51) Int. Cl. H01L 23/485; H01L 21/56

(52) U.S. Cl. 257/690; 438/113; 257/E23.021; 257/E21.502

(57) ABSTRACT

A package structure is provided that includes a metal plate; a semiconductor chip having an active surface, electrode pads disposed on the active surface, conductive bumps disposed on the electrode pads, and an inactive surface opposing the active surface and attached with the metal plate by a thermal conductive adhesive; an encapsulant formed on the metal plate for encapsulating a perimeter of the semiconductor chip, with the active surface of the semiconductor chip being exposed thereon; a first dielectric layer formed on the encapsulant and the active surface of the semiconductor chip, and having wiring trenches for exposing the conductive bumps; and a first wiring layer formed in the wiring trenches of the first dielectric layer and electrically connected to the conductive bumps. The wiring layer, through the electrical connection of the conductive bumps with the semiconductor chip prevents the use of bonding wires as a conductive pathway.

### BACKGROUND OF THE INVENTION

1. Field of the Invention

This invention relates to package structures and methods of fabricating the same, and, more particularly, to a thinned package structure and a method of fabricating the same.

2. Description of Related Art

With the rapid development of electronic industry, modern electronic products are manufactured to be low-profiled and compact-sized, and have to comply with Joint Electronic Device Engineering Council (JEDEC) standard. Therefore, how the electronic products are packaged is important. For instance, a dynamic random access memory (DRAM) has a dramatically reduced size, as small as 40 nm, for example. Though having the reduced size, the DRAM still has the same layout area. Therefore, the ball pitch of solder balls that are used by the package structure to support a circuit board has to be 0.8 mm, so as to comply with the JEDEC standard. Accordingly, a fan-out wafer level package is one of various packaging methods that may be employed therein. A double-data-rate three synchronous dynamic random access memory (DDR3 SDRAM) refers to a computer memory specification, and is generally packaged in a Window BGA manner.

Referring to FIG. 1, a cross-sectional view of a package structure 1 of a memory is shown according to the prior art. The package structure 1 has a packaging substrate 10 having a cavity 100 and a semiconductor chip 11 disposed on the packaging substrate 10 in a manner that an active surface 11a of the semiconductor chip 11 is attached to a bottom surface 10b of the packaging substrate 10 for covering one end of the cavity 100. Electrode pads 110 of the semiconductor chip 11 are thus positioned in the cavity 100. Wire-bonding pads 101 formed on a top surface 10a of the packaging substrate 10 are electrically connected to the electrode pads 110 by gold wires 12. A protection material 14 is then filled in the cavity 100, to encapsulate the gold wires 12. An encapsulant 13 is formed on the bottom surface 10b of the packaging substrate 10 and encapsulates the inactive surface 11b and side surfaces of the semiconductor chip 11. Ball implanting pads 102 are formed on the top surface 10a of the packaging substrate 10 for solder balls 16 to be implanted on the ball implanting pads 102, such that a circuit board can be disposed on the solder balls 16. The package structure 1 has an overall height (including the solder balls 16) approximately equal to 1.1-1.2 mm.

However, the gold wires 12 are used in the prior art as components for electrical connection. Accordingly, the height of the wireloop of each of the gold wires 12 has to be taken into account while forming the encapsulant 13. Therefore, it is hard to reduce the overall structural height. In other words, the gold wires 12 prevent the package structure 1 from complying with the low-profile and compact-size requirements.

As the memory needs more bandwidth, the gold wires 12, acting as a conductive pathway, have to have a certain length. Too long the length of the gold wires 12 affects the electrical efficacy such as the quality of inductors and capacitors. Accordingly, such a package structure does not meet the high bandwidth requirement.

The package structure 1 of the prior art has a high cost, because it uses the gold material as a conductive wire.

Therefore, how to overcome the various problems of the prior art is becoming one of the most concerned issues in the art.

### SUMMARY OF THE INVENTION

In view of the above-mentioned problems of the prior art, the present invention provides a package structure, including: a metal plate; a semiconductor chip having an active surface, electrode pads disposed on the active surface, conductive bumps disposed on the electrode pads, and an inactive surface opposing the active surface and attached to the metal plate by a thermal conductive adhesive; an encapsulant formed on the metal plate for encapsulating a perimeter of the semiconductor chip, and exposing the active surface of the semiconductor chip; a first dielectric layer formed on the encapsulant and the active surface of the semiconductor chip, and having wiring trenches for exposing the conductive bumps; and a first wiring layer disposed in the wiring trenches of the first dielectric layer and electrically connected to the conductive bumps.

The present invention further provides a method of fabricating a package structure, including: providing a carrier board and a semiconductor chip, the semiconductor chip having an active surface, an inactive surface opposing the active surface, electrode pads disposed on the active surface, and conductive bumps disposed on the electrode pads, wherein the active surface of the semiconductor chip is attached to the carrier board so as for the conductive bumps to be embedded in the carrier board; attaching a metal plate to the inactive surface of the semiconductor chip by a thermal conductive adhesive; forming between the carrier board and the metal plate an encapsulant that encapsulates a perimeter of the semiconductor chip; removing the carrier board, to expose the active surface of the semiconductor chip and the conductive bumps; forming a first dielectric layer on the encapsulant, the active surface of the semiconductor chip and the conductive bumps, and forming wiring trenches in the first dielectric layer for exposing the conductive bumps; and forming in the wiring trenches a first wiring layer that is electrically connected through the conductive bumps to the electrode pads.

In an embodiment of the present invention, the carrier board further has an adhesion layer for being attached to the active surface of the semiconductor chip, allowing the conductive bumps to be embedded in the adhesion layer. While the carrier board is removed, the adhesion layer is also removed. In an embodiment of the present invention, the method further comprising performing a singulation process.

In an embodiment of the present invention, an insulating protective layer is further formed on the first dielectric layer and the first wiring layer, and has a plurality of openings for exposing a part of the first wiring layer correspondingly, allowing solder balls to be implanted thereon. In another embodiment of the present invention, a built-up structure is formed on the first dielectric layer and the first wiring layer, and an insulating protective layer is formed on the built-up structure.

The package structure according to the present invention is packaged by an embedding method, and the first wiring layer is electrically connected to the semiconductor chip by the conductive bumps. Accordingly, there is no need to use gold wires as a conductive pathway, as does in the prior art. Therefore, the package structure according to the present invention has a reduced overall structural height and is thinner, as compared with the prior art. Moreover, the package structure according to the present invention has improved electrical efficacy, since the conductive bumps have a transmission pathway far shorter than that of the gold wires.

With the wiring trenches, whereby embedding the first wiring layer in the first dielectric layer, a number of process alignment is reduced, and the pitches of the solder balls can comply with the JEDEC standard.

The method according to the present invention does not need a wire bonding process. As such, the consumption of gold and the cost of material are reduced.

### BRIEF DESCRIPTION OF DRAWINGS

The invention can be more fully understood by reading the following detailed description of the preferred embodiments, with reference made to the accompanying drawings, wherein:

FIG. 1 is a cross-sectional view of a package structure of a memory according to the prior art; and

FIGS. 2A to 2H are cross-sectional views illustrating a method of fabricating a package structure according to an embodiment of the present invention.

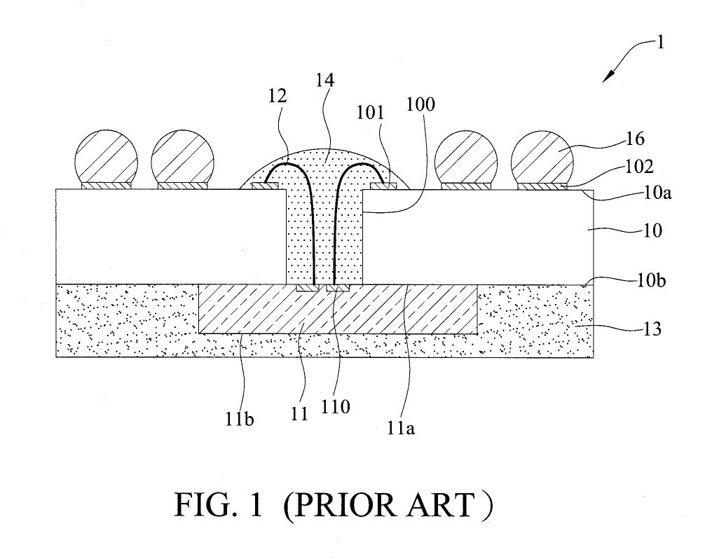

### DETAILED DESCRIPTION OF PREFERRED EMBODIMENTS

The following illustrative embodiments are provided to illustrate the disclosure of the present invention, with which those ordinarily skilled in the art can apparently understand these and other advantages and effects after reading the disclosure of this specification. The present invention can also be performed or applied by other different embodiments. The details of the specification can be described with different points and applications, and numerous modifications and variations can be devised without departing from the spirit of the present invention.

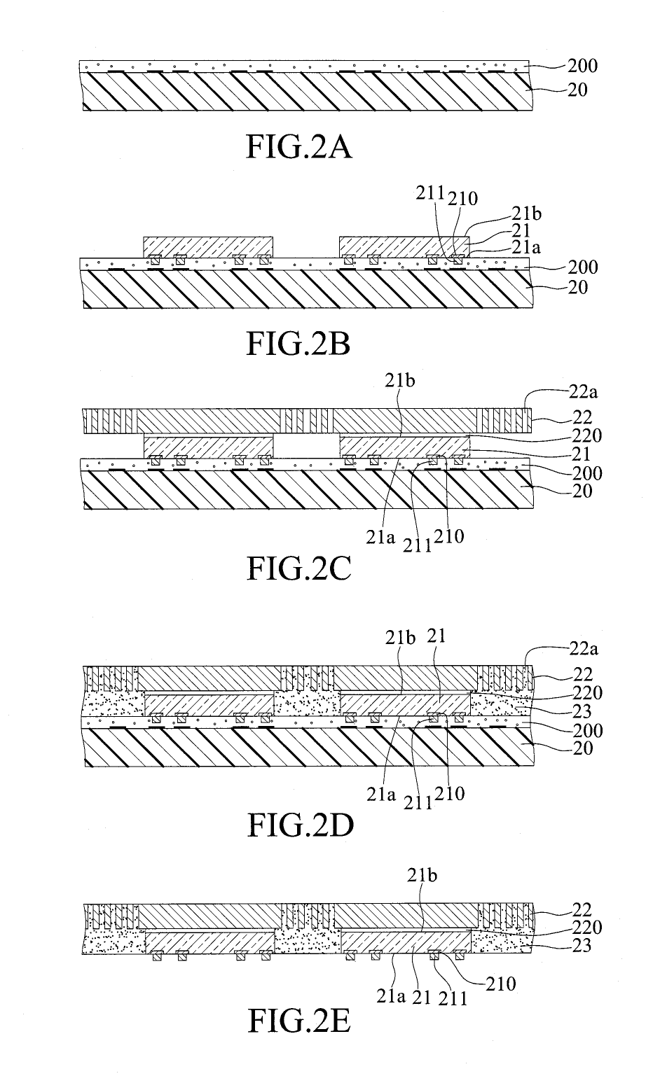

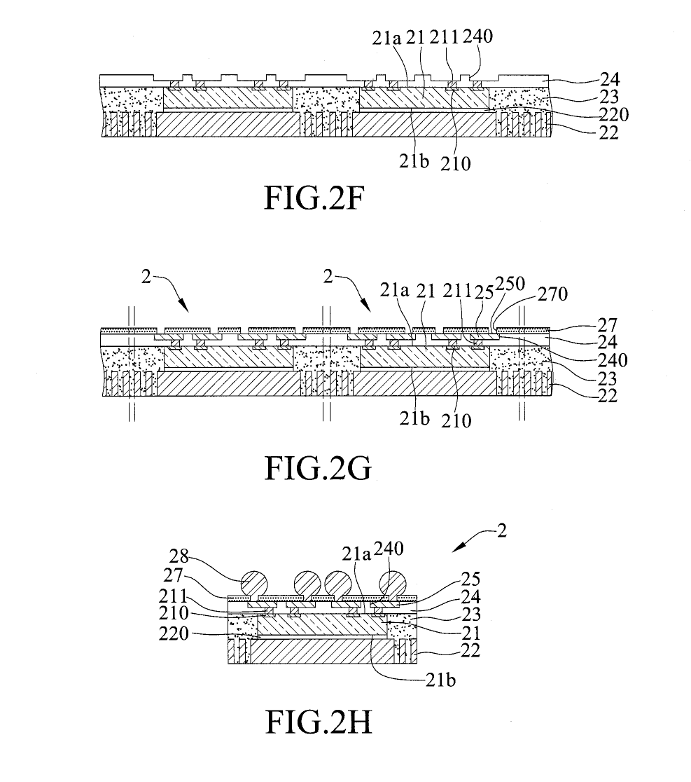

Referring to FIGS. 2A to 2H, cross-sectional views of a method of fabricating a package structure 2 are shown according to an embodiment of the present invention.

As shown in FIG. 2A, a carrier 20 having an adhesion layer 200 on one side thereof is provided.

As shown in FIG. 2B, a semiconductor chip 21 such as a memory chip is provided. The semiconductor chip 21 has an active surface 21a and an inactive surface 21b opposing the active surface 21a. Electrode pads 210 are disposed on the active surface 21a, and conductive bumps 211 are disposed on the electrode pads 210. The active surface 21a of the semiconductor chip 21 is attached to the adhesion layer 200 of the carrier board 20, allowing the conductive bumps 211 to be embedded in the adhesion layer 200.

In an embodiment of the present invention, the conductive bumps 211 may be electroplated bumps, copper pillars, or electroless Ni & immersion gold (ENIG).

As shown in FIG. 2C, a thermal conductive adhesive 220 is used to attach a metal plate 22 to the inactive surface 21b of the semiconductor chip 21. The metal plate 22 has through holes 22a that are disposed on a perimeter of the inactive surface 21b of the semiconductor chip 21. In an embodiment of the present invention, the metal plate 22 is a copper piece, whereby heat generated by the semiconductor chip 21 can be dissipated effectively. In another embodiment of the present invention, the metal plate 22 may be made of other materials.

As the frequency at which the memory is operating becomes higher, the greater the heat is generated by the chip. Therefore, the heat-dissipating function is one of the major concerns during a packaging process. With the use of the metal plate 22, the heat generated by the semiconductor chip 21 is dissipated to an ambient environment fast.

As shown in FIG. 2D, an encapsulant 23 is formed between the adhesion layer 200 and the metal plate 22, to encapsulate a perimeter of the semiconductor chip 21. In an embodiment of the present invention, the encapsulant 23 is filled through the through holes 22a in a space between the adhesion layer 200 and the metal plate 22, so as to encapsulate the perimeter of the semiconductor chip 21.

As shown in FIG. 2E, the carrier board 20 and the adhesion layer 200 are removed, so as to expose the active surface 21a of the semiconductor chip 21 and the conductive bumps 211, thereby allowing the conductive bumps to be protruded from the encapsulant 23.

As shown in FIG. 2F, a first dielectric layer 24 is formed on the encapsulant 23, the active surface 21a of the semiconductor chip 21, and the conductive bumps 211, and wiring trenches 240 are formed on the first dielectric layer 24 to expose top surfaces of the conductive bumps 211, wherein the top surfaces of the conductive bumps 211 align with bottom surfaces of the wiring trenches 240.

As shown in FIG. 2G, a first wiring layer 25 is formed in the wiring trenches 240, and is electrically connected through the conductive bumps 211 to the electrode pads 210. An insulating protective layer 27 such as a solder mask is formed on the first dielectric layer 24 and the first wiring layer 25, and formed with a plurality of openings 270, to expose a part of the first wiring layer 25 correspondingly, so as for the exposed part of the first wiring layer 25 to act as conductive pads. The whole package structure 2 is thus completely fabricated.

As shown in FIG. 2H, a singulation process is performed to obtain a plurality of single package structures 2. In an embodiment of the present invention, solder balls 28 such as solder tin are implanted, before or after the singulation process, on the exposed part of the first wiring layer 25 (conductive pads 250).

In another embodiment of the present invention shown in FIG. 2H, a built-up structure is formed on the first dielectric layer 24 and the first wiring layer 25, and then the insulating protective layer 27 that has the openings 270 is formed on the built-up structure. In an embodiment of the present invention, the built-up structure has at least a second dielectric layer, a second wiring layer formed on the second dielectric layer, and conductive vias formed in the second dielectric layer and electrically connected to the first wiring layer 25 and the second wiring layer. The second wiring layer has conductive pads that are exposed from the openings 270, for solder balls 28 to be implanted thereon. At last, the singulation process is performed so as to obtain a plurality of single package structure.

The method of fabricating the package structure 2 according to the present invention combines fan-out and built-up techniques, to package a memory chip by an embedding method, such that the first wiring layer 25 is electrically connected through the conductive bumps 211 to the semiconductor chip 21, without using gold wires as a conductive pathway, as did in the prior art. As a result, the package structure 2 according to the present invention has an overall structural height reduced, and an electrical efficacy (e.g., quality of inductors and capacitors) improved because the conductive bumps 211 have a conductive pathway far shorter than that of the gold wires. Therefore, the memory having the package structure according to the present invention can operate at a high frequency.

Since having a coreless structure, the package structure 2 according to the present invention does not need to use the packaging substrate of the prior art, and has an overall structural height reduced.

According to the method of the present invention, the wiring trenches 240 are formed on the first dielectric layer 24, and the first wiring layer 25 is embedded in the first dielectric layer 24. As such, the number of process alignment is reduced, and the solder balls 28 can have pitches that comply with the JEDEC standard.

According to the method of the present invention, no wire-bonding process is performed, less gold material is used and the fabrication cost is reduced.

The present invention further provides a package structure, which includes a metal plate such as copper, a semiconductor chip 21 attached to the metal plate 22, an encapsulant 23 formed on the metal plate 22 and encapsulating the perimeter of the semiconductor chip 21, a first dielectric layer 24 formed on the encapsulant 23, and a first wiring layer 25 formed in the first dielectric layer 24 and electrically connected to the semiconductor chip 21.

The semiconductor chip 21 has an active surface 21a and an inactive surface 21b opposing the active surface 21a. Electrode pads 210 are disposed on the active surface 21a, and conductive bumps 211 are disposed on the electrode pads 210. A thermal conductive adhesive 220 is employed to attach the inactive surface 21b of the semiconductor chip 21 with the metal plate 22.

The encapsulant 23 exposes the active surface 21a of the semiconductor chip 21, and the conductive bumps 211 are implanted on the encapsulant 23 in a protrusive manner.

The first dielectric layer 24 is further formed on the active surface 21a of the semiconductor chip 21, and has wiring trenches 240 for exposing top surfaces of the conductive bumps 211.

The first wiring layer 25 is formed in the wiring trenches 240, and electrically connected to the conductive bumps 211.

The package structure 2 further comprises an insulating protective layer 27 formed on the first dielectric layer 24 and the first wiring layer 25, and having a plurality of openings 270 for exposing a part of the first wiring layer 25 correspondingly, for solder balls 28 to be implanted thereon.

In another embodiment of the present invention, the package structure 2 further comprises a built-up structure formed on the first dielectric layer 24 and the first wiring layer 25, and having at least a second dielectric layer, a second wiring layer formed on the second dielectric layer, and conductive vias formed in the second dielectric layer and electrically connected to the first wiring layer 25, and the second wiring layer has conductive pads. Therefore, the insulating protective layer 27 is formed on the built-up structure, such that the conductive pads are exposed from the openings 270, allowing the solder balls 28 to be implanted on the conductive pads via the openings 270.

According to the method of fabricating a package structure of the present invention, the overall structural height of the package structure is reduced by embedding a semiconductor chip and using conductive bumps to electrically connect the wiring layer to the semiconductor chip, so as to achieve the objectives of thinning the package structure, improving the electrical efficacy, and complying with the JEDEC standard.

In a method of fabricating a package structure according to the present invention, the wire bonding method is not used. As such, the material cost is reduced.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A package structure, comprising:
a metal plate;
a semiconductor chip having an active surface, electrode pads disposed on the active surface, conductive bumps disposed on the electrode pads, and an inactive surface opposing the active surface and combined with the metal plate by a thermal conductive adhesive;
an encapsulant formed on the metal plate for encapsulating a perimeter of the semiconductor chip, with the active surface of the semiconductor chip being exposed from the encapsulant;
a first dielectric layer formed on the encapsulant and the active surface of the semiconductor chip, and having wiring trenches for exposing the conductive bumps; and
a first wiring layer formed in the wiring trenches of the first dielectric layer and electrically connected to the conductive bumps.

2. The package structure of claim 1, further comprising an insulating protective layer formed on the first dielectric layer and the first wiring layer, and having a plurality of openings for exposing a part of the first wiring layer correspondingly.

3. The package structure of claim 1, further comprising a built-up structure formed on the first dielectric layer and the first wiring layer, and having at least a second dielectric layer, a second wiring layer formed on the second dielectric layer, and conductive vias formed in the second dielectric layer and electrically connected to the first wiring layer and the second wiring layer, wherein the second wiring layer are formed with conductive pads.

4. The package structure of claim 3, further comprising an insulating protective layer formed on the built-up structure and having a plurality of openings for exposing the conductive pads, allowing solder balls to be implanted on the conductive pads.

5. A method of fabricating a package structure, comprising:
providing a carrier board having an adhesion layer and a semiconductor chip having an active surface, an inactive surface opposing the active surface, electrode pads disposed on the active surface, and conductive bumps disposed on the electrode pads, wherein semiconductor chip is attached to the adhesion layer on the carrier board via the active surface thereof, allowing the bumps to be embedded in the adhesion layer;
combining a metal plate with the inactive surface of the semiconductor chip by a thermal conductive adhesive;
forming between the carrier board and the metal plate an encapsulant that encapsulates a perimeter of the semiconductor chip;
removing the carrier board to expose the active surface of the semiconductor chip and the conductive bumps;
forming a first dielectric layer on the encapsulant, the active surface of the semiconductor chip and the conductive bumps, and forming wiring trenches on the first dielectric layer for exposing the conductive bumps; and
forming in the wiring trenches a first wiring layer that is electrically connected through the conductive bumps to the electrode pads.

6. The method of claim 5, wherein the metal plate is further formed with a plurality of through holes that can be filled with an encapsulating material for forming the encapsulant.

7. The method of claim 6, wherein the adhesion layer is removed while the carrier board is removed.

8. The method of claim 5, further comprising forming on the first dielectric layer and the first wiring layer an insulating protective layer that has a plurality of openings for exposing a part of the first wiring layer.

9. The method of claim 8, further comprising performing a singulation process after the formation of the insulating protective layer.

10. The method of claim 5, further comprising forming on the first dielectric layer and the first wiring layer a built-up structure that has at least a second dielectric layer, a second wiring layer formed on the second dielectric layer, and conductive vias formed in the second dielectric layer and electrically connected to the first wiring layer and the second wiring layer wherein the second wiring layer are formed with conductive pads.

11. The method of claim 10, further comprising forming on the built-up structure an insulating protective layer that has a plurality of openings for exposing the conductive pads, allowing solder balls to be implanted on the conductive pads.

12. The method of claim 11, further comprising performing a singulation process after the formation of the insulating protective layer.
